(19) United States
(12) Patent Application Publication
(10) Pub. No.: US 2018/0259854 A1
(43) Pub. Date: Sep. 13, 2018

(54) BEARING TABLE AND FABRICATION METHOD THEREOF AND PROCESSING DEVICE AND OPERATION METHOD THEREOF

(71) Applicant: BOE TECHNOLOGY GROUP CO., LTD., Beijing (CN)

(72) Inventors: Xiaolei Zhang, Beijing (CN); Jinxiang XUE, Beijing (CN); Xiaohu WANG, Beijing (CN)

(21) Appl. No.: 15/828,514

(22) Filed: Dec. 1, 2017

(30) Foreign Application Priority Data
Mar. 10, 2017 (CN) CN 201710144407.5

(51) Int. Cl. G03F 7/16; G03F 7/20; C23C 14/50; G03F 7/00

(52) U.S. Cl. CPC G03F 7/164; G03F 7/70733; G03F 7/0035; C23C 14/50; G03F 7/2002

(57) ABSTRACT

A bearing table and a fabrication method thereof as well as a processing device and an operation method thereof. The bearing table includes a bearing substrate; an electrically conductive layer disposed on the bearing substrate; and an insulation layer covering the electrically conductive layer disposed on the bearing substrate. The electrically conductive layer is configured to provide electrostatic adsorption. conductive layer

### TECHNICAL FIELD

Embodiments of the present disclosure relate to a bearing table and a fabrication method thereof as well as a processing device and an operation method thereof.

### BACKGROUND

Existing bearing tables are generally comprises metallic or marble structures. In order to fix an object to be processed (for example, a surface plate) onto the bearing table, the bearing table usually utilizes fixture boards or vacuum suction force generated by additional vacuum pipes of the bearing table. However, conventional methods for fixing the object lead to bearing tables with complicated structures, such that costs of the bearing tables are increased and working efficiency of the bearing tables is adversely limited.

### SUMMARY

For example, at least one embodiment of the present disclosure provides a bearing table, which comprises: a bearing substrate; an electrically conductive layer on the bearing substrate and configured to provide electrostatic adsorption; and an insulation layer covering the electrically conductive layer on the bearing substrate.

For example, the bearing table provided by the at least one embodiment of the present disclosure further comprises an electrostatic generator coupled to the electrically conductive layer and configured to provide static electricity to the electrically conductive layer.

For example, for the bearing table provided by the at least one embodiment of the present disclosure, the bearing substrate and the insulation layer are transparent.

For example, for the bearing table provided by the at least one embodiment of the present disclosure, the insulation layer comprises silicon nitride, silicon oxide or silicon oxynitride.

For example, for the bearing table provided by the at least one embodiment of the present disclosure, the electrically conductive layer is a layer of wire pattern, the wire pattern comprises one or any combination of a polyline pattern, a camber line pattern, a homocentric squares pattern and a grid pattern.

For example, for the bearing table provided by the at least one embodiment of the present disclosure, the wire pattern comprises a transparent conductive material.

For example, for the bearing table provided by the at least one embodiment of the present disclosure, the electrically conductive layer is a layer of wire pattern, the wire pattern comprises one or any combination of a polyline pattern, a camber line pattern, a homocentric squares pattern and a grid pattern.

For example, for the bearing table provided by the at least one embodiment of the present disclosure, the electrically conductive layer is a layer of wire pattern, the wire pattern comprises one or any combination of a polyline pattern, a camber line pattern, a homocentric squares pattern and a grid pattern.

For example, for the bearing table provided by the at least one embodiment of the present disclosure, the electrically conductive layer is a layer of wire pattern, the wire pattern comprises one or any combination of a polyline pattern, a camber line pattern, a homocentric squares pattern and a grid pattern.

For example, at least one embodiment of the present disclosure further provides a processing device including any one of the above-mentioned bearing tables.

For example, for the processing device provided by the at least one embodiment of the present disclosure, the processing device further comprises a coating head configured to apply a coating onto a surface plate to be processed that is placed on the bearing table.

For example, for the processing device provided by the at least one embodiment of the present disclosure, the processing device further comprises a detection unit disposed on a side of the bearing substrate far away from the electrically conductive layer and configured to detect a line width of the coating.

For example, for the processing device provided by the at least one embodiment of the present disclosure, the processing device further comprises an exposure source, the exposure source is configured to perform an exposure operation via a mask plate adsorbed onto the bearing table.

For example, for the processing device provided by the at least one embodiment of the present disclosure, the processing device further comprises an exposure source, the exposure source is configured to perform an exposure operation via a mask layer disposed on a surface plate to be processed.

For example, at least one embodiment of the present disclosure further provides a fabrication method of a bearing table, which comprises: providing a bearing substrate; forming an electrically conductive layer on the bearing substrate, and the electrically conductive layer is operable to provide electrostatic adsorption; and forming an insulation layer on the electrically conductive layer.

For example, for the fabrication method provided by the at least one embodiment of the present disclosure, the fabrication method further comprises: providing an electrostatic generator coupled to the electrically conductive layer.

For example, for the fabrication method provided by the at least one embodiment of the present disclosure, the fabrication method further comprises: enabling electrostatic adsorption via the electrically conductive layer.

For example, at least one embodiment of the present disclosure further provides an operation method for the above-mentioned processing device, which comprises: applying a coating onto a surface plate to be processed that is adsorbed onto the bearing table.

For example, for the fabrication method provided by the at least one embodiment of the present disclosure, the fabrication method further comprises: performing an exposure operation to a surface plate to be processed that is adsorbed onto the bearing table via a mask plate adsorbed onto the bearing table.

For example, for the fabrication method provided by the at least one embodiment of the present disclosure, the fabrication method further comprises: performing an exposure operation to a surface plate to be processed that is disposed with a mask layer and adsorbed onto the bearing table.

### BRIEF DESCRIPTION OF THE DRAWINGS

In order to clearly illustrate the technical solution of the embodiments of the disclosure, the drawings of the embodiments can be briefly described in the following; it is obvious that the described drawings are only related to some embodiments of the disclosure and thus are not limitative of the disclosure.

FIG. 1A is a schematically structural view of a bearing table provided by an embodiment of the present disclosure;

FIG. 1B is a schematically structural top view of the bearing table illustrated in FIG. 1A;

FIG. 1C is a cross-sectional view taken along line AB of the bearing table illustrated in FIG. 1B;

FIG. 2 is a schematic diagram illustrating wire patterns provided by an embodiment of the present disclosure;

FIG. 3 is a cross-sectional view illustrating a processing device provided by an embodiment of the present disclosure;

FIG. 4A is a cross-sectional view illustrating another processing device provided by an embodiment of the present disclosure; and

FIG. 4B is a cross-sectional view illustrating further another processing device provided by an embodiment of the present disclosure.

### REFERENCE NUMERALS

100—bearing substrate; 200—electrically conductive layer; 300—electrostatic generator; 400—insulation layer; 500—surface plate; 510—first substrate; 520—second substrate; 530—mask plate; 540—coating; 600—exposure source; 700—coating head; 800—detection unit.

### DETAILED DESCRIPTION

In order to make objects, technical details and advantages of the embodiments of the disclosure apparent, the technical solutions of the embodiments can be described in a clearly and fully understandable way in connection with the drawings related to the embodiments of the disclosure. Apparently, the described embodiments are just a part but not all of the embodiments of the disclosure. Based on the described embodiments herein, those skilled in the art can obtain other embodiment(s), without any inventive work, which should be within the scope of the disclosure.

Unless otherwise defined, all the technical and scientific terms used herein have the same meanings as commonly understood by one of ordinary skill in the art to which the present disclosure belongs. The terms “first,” “second,” and the like, which are used in the description and the claims of the present application for disclosure, are not intended to indicate any sequence, amount or importance, but distinguish various components. Also, the terms such as “a,” “an,” and etc., are not intended to limit the amount, but indicate the existence of at least one. The terms “comprise,” “comprising,” “include,” “including,” and the like, are intended to specify that the elements or the objects stated before these terms encompass the elements or the objects and equivalents thereof listed after these terms, but do not preclude the other elements or objects. The phrases “connect”, “connected”, and the like, are not intended to define a physical connection or mechanical connection, but can include an electrical connection, directly or indirectly. “On,” “under,” “right,” “left” and the like are only used to indicate relative position relationship, and when the position of the object which is described is changed, the relative position relationship may be changed accordingly.

For existing bearing tables methods for fixing an object to be processed (for example, a surface plate) are quite complicated, and thus working efficiency of processing devices equipped with those bearing tables is hard to improve and reject ratios of products are increased. For example, for fixation of the surface plate through snap-fits, operation methods of the bearing tables are relatively complex and the surface plate can be damaged; for fixation of the surface plate through vacuum adsorption, power consumption can be relatively high, faults can be hard to remove, and structures of the bearing tables are complicated.

Performing a plurality of manufacture procedures in parallel can be hard for processing devices equipped with the existing bearing tables because of complex structures of the existing bearing tables. For example, during packaging and fixing processes of a product, due to the complex structure and low transparency of the bearing table, manufacture procedures are generally performed from one side of the bearing table and as a result it is difficult to perform a plurality of manufacture procedures (such as coating, detecting, curing, and the like) in parallel. For example, for an existing processing device, packaging and curing processes can comprises the following steps: firstly, curing a few points in the product to stabilize a structure of the product in one manufacture procedure; secondly, performing an overall curing process to the entire product in a subsequent manufacture procedure; for the above-mentioned bearing tables and processing device, the quality of the manufactured product can be poor due to a limited fixation area, a number of manufacture procedures are increased and production efficiency of the manufactured product is adversely limited.

Embodiments of the present disclosure provide a bearing table and a fabrication method thereof as well as a processing device and an operation method thereof, so as to solve the above-mentioned problems. The bearing table includes a bearing substrate, an electrically conductive layer disposed on the bearing substrate and an insulation layer covering the electrically conductive layer disposed on the bearing substrate. The electrically conductive layer is configured to provide electrostatic adsorption.

For example, in an embodiment of the present disclosure, the bearing table can comprises a static electricity generating unit (for example, an electrostatic generator) the static electricity generating unit can be connected with the electrically conductive layer to provide static electricity thereto, so as to fix an object to be processed (such as a surface plate, a mask plate or the like) onto the bearing table by means of electrostatic adsorption. In this way, the structure of the bearing table is simplified, the fixation method of the surface plate to be processed, the mask plate or the like onto the bearing table is simplified, and thus costs are reduced and the operation efficiency of the bearing table is improved.

For example, there are various means to provide static electricity to the electrically conductive layer, and no specific limitation will be given here in the embodiment of the present disclosure. However, in order to facilitate comprehension of technical solutions provided by the present disclosure, description of the following embodiments provided by the present disclosure is given by taking a case that the electrically conductive layer is provided with static electricity by an electrostatic generator.

The electrostatic adsorption of the bearing table provided by the embodiments has a high strength and good persistence, and can be adjusted as required. Furthermore, influence of external factors such as moisture and the like on the electrostatic adsorption force can be avoided by an insulation arrangement (for example, the insulation layer). For example, in a case that the electrostatic generator is turned off, the adsorbed object can be released rapidly, that is, the bearing table can have a quick response. Because no electrostatic adsorption force is generated before, for example, the bearing table is in operation, failures such as binding of the product onto the bearing table due to delay of operation when using a vacuum device can be avoided. Therefore, the fixation method of, for example, the surface plate to be processed onto the bearing table through electrostatic adsorption is simple, safe and fast.

It should be noted that the technical solutions of fixation of the surface plate onto the bearing table provided by the embodiments of the present disclosure can be applied to any objects need to be fixed and is not limited to the fixation of the surface plate. In order to facilitate explanation of the technical solution of the present disclosure, the embodiments of the present disclosure is described with the surface plate being taken as an example of the object to be processed, and in some embodiments, the surface plate, for example, can be a display panel.

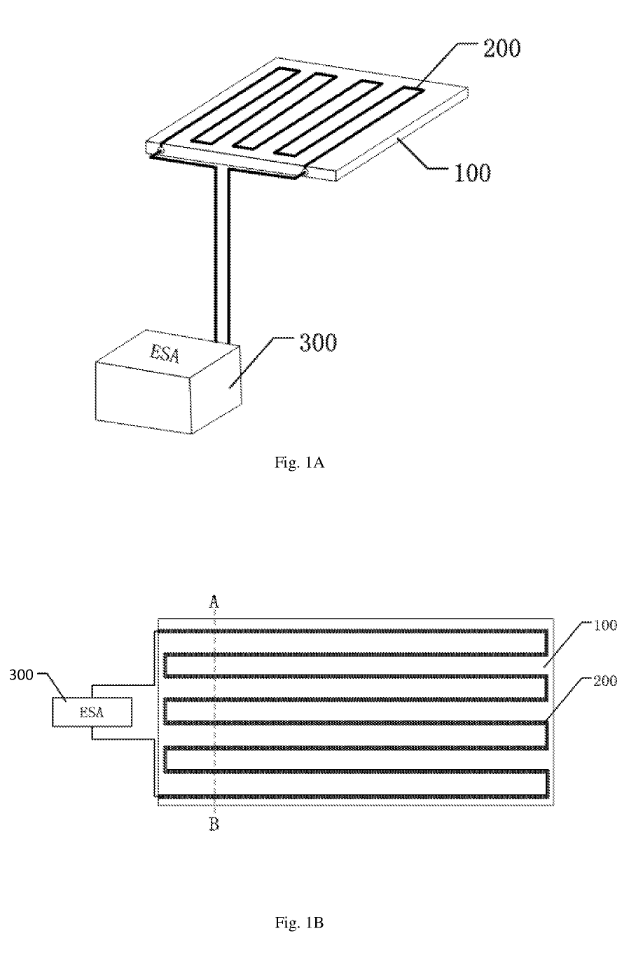

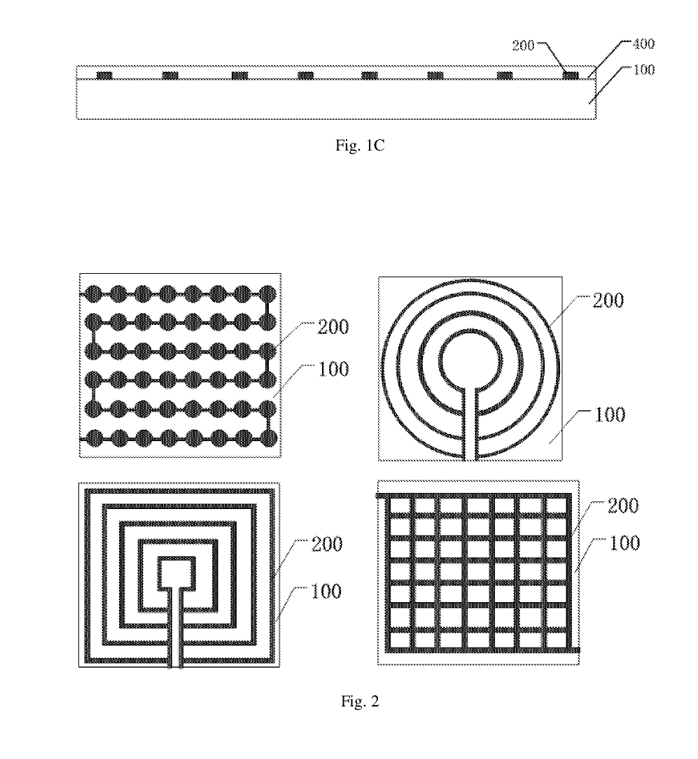

FIG. 1A is a schematically structural view of a bearing table provided by an embodiment of the present disclosure and FIG. 1B is a top view of the bearing table illustrated in FIG. 1A. For example, as illustrated in FIG. 1A and FIG. 1b, the bearing table can include a bearing substrate 100, an electrically conductive layer 200 disposed on the bearing substrate 100, and an insulation layer (not illustrated in the FIG. 1A and FIG. 1b, see the insulation layer 400 in FIG. 1C) covering the electrically conductive layer 200 disposed on the bearing substrate 100. For example, as illustrated in FIG. 1A and FIG. 1b, the bearing table can further include an electrostatic generator 300 that is connected with the electrically conductive layer. For example, the electrostatic generator 300 is coupled to the electrically conductive layer 200 via wires, and the electrostatic adsorption function of the electrically conductive layer 200 (or the bearing table) can be turned on or turned off respectively by charging (providing static charges to) or discharging the electrically conductive layer 200, for example, through the electrostatic generator 300. For example, the magnitude of the electrostatic adsorption force can be adjusted by a static voltage outputted by the electrostatic generator 300.

Illustratively, in a case that the surface plate to be processed needs to be fixed on the bearing table, the electrostatic generator 300 applies the static voltage and provides static electricity to the electrically conductive layer 200, the electrostatic adsorption between the electrically conductive layer and the surface plate to be processed that is provided on the bearing table is accordingly generated, and thus the surface plate to be processed can be fixed onto the bearing table; in a case that the surface plate to be processed needs to be released from the bearing table, the electrostatic generator 300 leads out the static electricity on the electrically conductive layer 200 and the electrostatic adsorption between the electrically conductive layer 200 and the surface plate to be processed that is provided on the bearing table vanishes because the static charges on the electrically conductive layer 200 disappears, and thus the surface plate to be processed can be separated from the bearing table.

For example, in some embodiment of the present disclosure, in order to allow the electrically conductive layer disposed on the bearing table to achieve good electrostatic effects, a current intensity after the static voltage being applied to the electrically conductive layer by the electrostatic generator can be relatively small. For example, the maximum instant current can be less than or equal to 1 mA.

FIG. 1C is a cross-sectional view taken along line AB of the bearing table illustrated in FIG. 1B. For example, as illustrated in FIG. 1C, the insulation layer 400 covers the electrically conductive layer 200. The insulation layer 400 separates the electrically conductive layer 200 from the surface plate to be processed that is provided on the insulation layer 400, so as to prevent the electrostatic adsorption from being invalid due to direct contact of the electrically conductive layer 200 and the surface plate to be processed.

For example, the insulation layer 400 can be formed of organic or inorganic insulating materials, which can isolate static electricity. For example, the material used to form the insulation layer 400 can be silicon oxide, silicon nitride, silicon oxynitride or the like.

For example, the insulation layer 400 can be planarized, that is to say, a surface of the insulation layer 400 far away from the bearing substrate 100 can be a flat surface, so as to guarantee processing quality for the surface plate to be processed in subsequent processes.

For example, a thickness of the electrically conductive layer 200 can be minimized to allow the surface of the bearing table (i.e. the surface of the insulation layer 400) as flat as possible. For example, the thickness of the electrically conductive layer 200 can be a few microns or even smaller.

The thickness of the insulation layer 400 can be chosen based on practical manufacturing processes, as long as it can guarantee the electrostatic adsorption force and prevent the electrostatic breakdown of the insulation layer 400 caused by the static electricity on the electrically conductive layer 200. For example, the material of the insulation layer 400 can be silicon oxide, which has an electrostatic breakdown voltage of about 43 Volts per micron of thickness at 20 degrees centigrade; a thickness of the insulation layer 400 can be greater than 25 microns in a case that the static voltage is designed to be 1000 Volts. For example, the material of the insulation layer 400 can also be silicon nitride, which has an electrostatic breakdown voltage of up to 1200 Volts per micron of thickness, so that in a case that the static voltage is designed to be 1000 Volts, a minimum thickness of the insulation layer 400 can be less than 1 micron.

In a case that the thickness of the electrically conductive layer 200 is being taken into consideration and/or the effect of preventing the insulation layer 400 from being locally thinned (due to, for example, scratching) need to be achieved, the thickness of the insulation layer can be increased appropriately; for example, the thickness of the thinnest portion of the insulation layer 400 can range from 10 microns to 1000 microns.

For example, in some embodiment of the present disclosure, the electrically conductive layer can be a planar structure (i.e., having a plate-shaped pattern). For the electrically conductive layer, being a planar structure can potentially cause a series of problems, such as delay of electrostatic discharge etc., and as a result when the electrostatic generator is turned off, electrostatic adsorption can still reside on the bearing table and the surface plate is not ready to be removed.

For example, in some embodiment of the present disclosure, the electrically conductive layer can be a wire pattern layer. FIG. 2 is a schematic diagram illustrating the wire patterns provided by an embodiment of the present disclosure. For example, as illustrated in FIG. 2, the wire pattern can be one or any combination of a polyline pattern, a camber line pattern, a homocentric squares pattern and a grid pattern. For example, a pattern of the electrically conductive layer provided by the embodiment of the present disclosure is not limited to the wire patterns illustrated in FIG. 2, the electrically conductive layer can adopt other wire patterns as long as the distribution of the leads on the bearing substrate enables the surface plate to be processed to be fixed by electrostatic adsorption. In a case that the electrically conductive layer is a wire pattern layer, the distribution of the leads in the wire pattern layer allows the static charges to be uniformly distributed, so as to uniform distribution of electrostatic adsorption can be achieved.

For example, in an embodiment of the present disclosure, the wire pattern can be formed in various ways. For example, a linear wire pattern can be formed on the bearing substrate directly by means of a masking (for example, using a linear pattern) or printing process, for example, the polyline pattern can be formed with the above-mentioned linear wire patterns. For another example, the wire pattern can also be formed by the following steps: forming a conducting film on the bearing substrate at first and then performing a patterning process to the conducting film to form the wire pattern.

For example, the wire pattern is not limited to be formed on the bearing substrate; the wire pattern can also be formed to be embedded into the bearing substrate. For example, connecting terminals can also be formed at ends of the wire pattern to facilitate later connection with the electrostatic generator. For example, the structure of the bearing substrate with embedded wire pattern is similar to FIG. 1c, the differences are the insulation layer 400 and the bearing substrate 100 being formed with a same material, and connecting terminals (not illustrated in FIG. 1c) being formed and connected to the wire pattern.

In the embodiment, the patterning process can be a photolithographic process, the photolithographic process, for example, can include the following steps: coating a photoresist layer onto the electrically conductive layer to be patterned; performing an exposure process to the photoresist layer with a mask plate; developing the exposed photoresist layer to obtain a photoresist pattern, and etching the electrically conductive layer using the photoresist pattern; optionally, the photolithographic process can also comprises a step of removing the photoresist pattern.

For example, in an embodiment of the present disclosure, the leads in the wire pattern can be formed of a conducting material, the conducting material can be a transparent conductive material, such as indium tin oxide, indium zinc oxide etc. For example, a light transmittance of the wire pattern of larger than 75% can provide a good effect of light transmission. For example, the light transmittance of the wire pattern can be larger than 90%, for example, larger than 95%. For example, in an embodiment of the present disclosure, the bearing substrate and the insulation layer can be transparent. In a case that the bearing substrate, the electrically conductive layer (wire pattern) and the insulation layer in the bearing table are all transparent, the bearing table is transparent, and thus the surface plate to be processed can be manufactured from different sides of the bearing table. For example, the surface plate can be processed with a processing element (for example, a detection unit) located at a side of the bearing table far away from the surface plate (see FIG. 4A and FIG. 4B). For example, manufacturing procedures can be performed in parallel from different sides of the bearing table. Relevant embodiments of a processing device described in the following can be referenced for more details.

For example, in an embodiment of the present disclosure, the material of the bearing substrate can be a transparent material. For example, the bearing substrate can be a glass substrate, a quart substrate, a plastic substrate (for example, a PET substrate) or a substrate made from other suitable materials.

At least one embodiment of the present disclosure provides a processing device including the bearing table in any one of the embodiments described above.

For example, in an embodiment of the present disclosure, the processing device can include a coating head configured to apply a coating onto the surface plate to be processed that is placed on the bearing table.

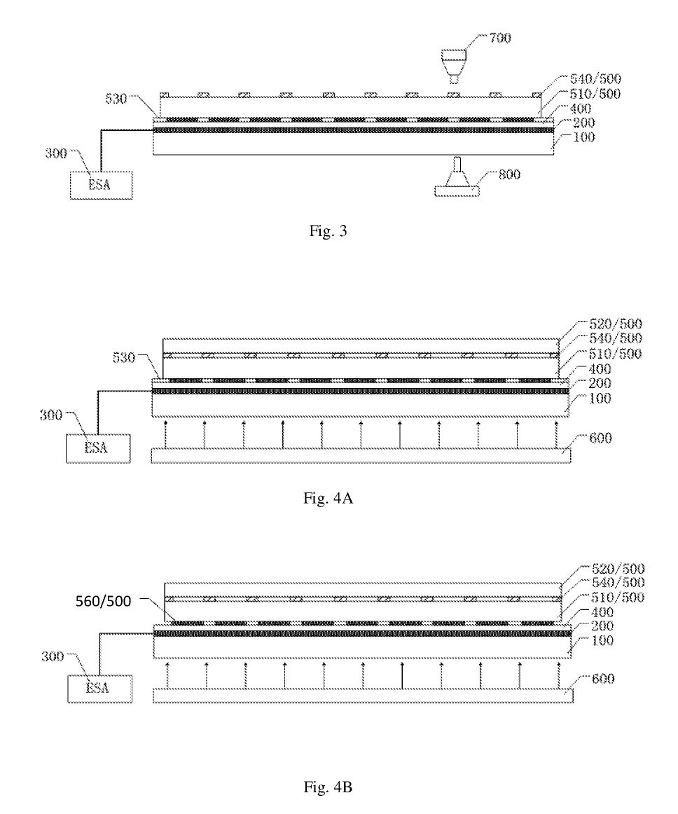

FIG. 3 is a cross-sectional view illustrating a processing device provided by an embodiment of the present disclosure. For example, as illustrated in FIG. 3, the processing device includes a bearing table and a coating head 700. The coating head 700 can be controlled by, for example, a coating device to apply a coating 540 onto the surface plate to be processed. For example, the coating can be a sealant used in a packaging process for an OLED display panel, a sealant used in an assembling process for a liquid crystal panel or the like. For example, the sealant can bind different substrates, for example, a first substrate 510 and a second substrate (not illustrated in the figure FIG. 3, see the second substrate 520 illustrated in FIG. 4A for reference), of the surface plate 500 together. For example, the surface plate 500 can be a display panel and the coating 540 can be used to bind the array substrate and the opposed substrate together during fabrication of the display panel.

A line width of the coating has an influence on the product yield. In an embodiment of the present disclosure, the processing device can further include a detection unit disposed on the side of the bearing substrate far away from the electrically conductive layer. For example, as illustrated in FIG. 3, in a case that the bearing table is transparent (see the corresponding contents in the embodiments described above for reference), the coating head 700 can apply the coating 540 onto the upper surface (the surface far away from the bearing table) of the surface plate 500, and the detection unit 800 can detect the line width of the coating 540 on the surface plate 500 in real time through the bearing table from a side of the lower surface (i.e., the surface face toward the bearing table) of the surface plate 500. The detection unit 800 can, for example, be coupled to the coating device equipped with the coating head 700 to guarantee the quality of the coating 540. For example, the coating device can coat portions with unqualified line width again, enabling the coating 540 to have a desired line width and uniform distribution. For example, the detection unit 800 can be a camera, the camera, for example, can be connected with a controller (e.g., a central processor (CPU)). The controller obtains and analyzes images acquired by the detection unit 800 to determine whether the line width of the applied coating satisfies requirements.

For example, in an embodiment of the present disclosure, the processing device can be equipped with an alarm unit connected to the detection unit. For example, the detection unit can have a line width threshold set therein. For example, in a case that the real-time line width information detected by the detection unit indicates that the line width of the coating is equal to or larger than the line width threshold, the alarm device is activated such that manual interference can be introduced and thus the product yield can be guaranteed.

For example, in an embodiment of the present disclosure, the processing device can further be equipped with an exposure source, which can be configured for performing exposure operation via a mask plate adsorbed onto the bearing table or a mask layer disposed on the surface plate to be processed; for example, the exposure source can perform an exposure operation to the photoresist applied, for example, onto the surface plate, such that the patterning process can be realized; for another example, the exposure source can perform exposure operation on the sealant, such that the curing process can be realized.

FIG. 4A is a cross-sectional view illustrating another processing device provided by an embodiment of the present disclosure. For example, as illustrated in FIG. 4A, the exposure source 600 can be disposed on the side of the bearing table far away from the surface plate 500; for example, the surface plate 500 can include, the first substrate 510, the second substrate 520 and the coating 540 for binding the first and second substrates together; for example, a mask plate 530 can be provided and adsorbed onto the bearing table. For example, the exposure source 600 can perform the exposure and curing operation to the coating 540 (e.g., sealant) on the surface plate 500 via the mask plate 530.

For example, the mask plate can be fabricated by forming, for example, a metal layer on a glass substrate. The metal layer can have a shape and a layout corresponding to those of the coating on the surface plate to be processed, and can be formed by photolithography, screen printing or the like to reduce costs and form various types of patterns flexibly. The mask plate manufactured by the above-mentioned method can be referred as a glass mask plate. The glass mask plate can be electrostatically adsorbed onto the bearing table provided by the embodiments of the present disclosure and can replace the specialized ultraviolet (UV) mask plate to reduce manufacture costs and simplify manufacture processes.

For example, the coating 540 to be processed by the exposure operation is not limited to the sealant (for example, illustrated in FIG. 4a), the coating to be processed by the exposure operation can also be a photoresist, which can form a photoresist pattern after being exposed and developed. The obtained photoresist pattern can serve as an etching mask during subsequent (wet or dry) etching processes.

It should be noted that, the exposure operation can be performed with the mask plate 530 provided and adsorbed onto the bearing table or can be performed with the mask layer 560 directly disposed on the product (e.g. the surface plate) to be processed, for example, the mask layer can be disposed on a side of the product nearer to the bearing table.

For example, in an example of the present disclosure, as illustrated in FIG. 4A, the mask plate 530 is provided and adsorbed onto the bearing table. The mask plate 530 illustrated in FIG. 4A is suitable for a case that the processing device is used to produce products (e.g. the surface plates) with a single specification or a few specifications; because a small number of replacement of the mask plate 530 is needed, a plurality of the surface plates 500 can be processed (e.g., exposure process) with each mask plate 530, and thus the costs can be reduced through using the mask plate 530 adsorbed onto the bearing table.

For example, in an example of the present disclosure, the processing device can be used to produce products with various specifications. Due to the various specifications, the mask plate 530 provided on the bearing table directly has to be replaced frequently. Moreover, the mask plate provided on the bearing table is expensive and as a result costs are increased. In view of this, the mask layer 560 directly disposed on the side of the product nearer to the bearing table can be adopted. FIG. 4B is a cross-sectional view illustrating further another processing device provided by an embodiment of the present disclosure. For example, as illustrated in FIG. 4B, a film layer, which can block light, can be formed on the surface plate 500 (by, for example, evaporation or sputtering) at first, and then a mask layer 560 having the same function as the mask plate 530 can be obtained (through, for example, patterning processes). The manufacturing process of the mask layer 560 can be performed in parallel with the production of the surface plate 500 to reduce processing steps. Moreover, in a case that the surface plate 500 and the mask layer are fabricated concurrently, corresponding parameters, such as the shape and layout of the product, can be utilized in the manufacturing process of the mask layer 560, such that fabrication costs can be reduced. In the embodiment, the surface plate to be processed is adsorbed onto the bearing table so as to subject to the exposure operation or other operations.

It should be noted that the mask plate 530 or the mask layer 560 is intended to protect elements susceptible to light irradiation of the exposure source from being damaged by the exposure source. For example, in a case that the surface plate is a display panel, electrical properties of thin-film transistor elements of the display panel can be affected by the light irradiation of the exposure source, leading to a decreased display quality of the display panel. In a case that the elements in the surface plate is not affected by the light irradiation of the exposure source, the bearing table of the processing device provided by the present embodiment can have no mask plate 530 disposed thereon; for similar reasons, it's not necessary to dispose mask layer 560 on the surface plate to be processed too.

For example, in an embodiment of the present disclosure, the exposure source can be an ultraviolet (UV) exposure source, and the exposure source can be used in the exposure process of the photoresist or in the curing process of the sealant.

At least one embodiment of the present disclosure further provides a fabrication method for a bearing table, the method includes the following steps: providing a bearing substrate; forming an electrically conductive layer on the bearing substrate, and the electrically conductive layer is capable of providing electrostatic adsorption; and forming an insulation layer on the electrically conductive layer. For example, the fabrication method provided by the present embodiment further includes a step of providing an electrostatic generator coupled to the electrically conductive layer.

For example, in an example of the embodiment of the present disclosure, the fabrication method for the bearing table can include the following steps.

Step S1, providing a bearing substrate.

In step S1, the bearing substrate can be formed of transparent material such as glass, ceramic or the like, for example, the transparent material can be quartz glass.

Step S2, forming an electrically conductive layer on the bearing substrate.

In step S2, the electrically conductive layer can be, for example, a wire pattern. For example, the wire pattern can comprises linear wire patterns, and the linear wire patterns can be formed directly on the bearing substrate by masking (e.g., using a linear pattern) processes, printing processes or any other suitable processes. For another example, the wire pattern can also be formed by the following steps: forming a conducting film on the bearing substrate at first and then performing a patterning process (for example, photolithography) on the conducting film to form the wire pattern.

Step S3, forming an insulation layer on the electrically conductive layer.

In step S3, the insulation layer, for example, can cover the electrically conductive layer completely. For example, the material of the insulation layer can be silicon oxide, silicon nitride, silicon oxynitride or the like, and the insulation layer can be formed onto the bearing substrate by, for example, chemical vapor deposition or physical vapor deposition. For example, the material of the insulation layer can also be other organic or inorganic insulating material, as long as it can allow the electrically conductive layer to realize an insulation function. For example, the surface of the insulation layer can be planarized, and the advantages of the planarization of the surface of the insulation layer have been described in some embodiments of the present disclosure above and no further description will be given herein.

At least one embodiment of the present disclosure provides an operation method for the processing device in accordance with at least one embodiment of the present disclosure, the method including a step of providing static electricity to the electrically conductive layer (through, for example, controlling the electrostatic generator) so as to provide electrostatic adsorption, and therefore, the surface plate to be processed can be adsorbed onto the bearing table.

For example, in some embodiments, the operation method provided by at least one embodiment of the present disclosure can further include a step of applying a coating onto a surface of the surface plate to be processed that is adsorbed onto the bearing table. For example, a coating head is used to apply the coating onto the surface of the surface plate to be processed that is adsorbed onto the bearing table. For example, the surface plate to be processed can be any substrates of a display panel. The coating can be a sealant used in the packaging process of an OLED display panel, a sealant used in the assembling process of a liquid crystal panel or the like. The coating can also be a photoresist used in a photolithographic process or the like.

For example, in some embodiments, the operation method provided by at least one embodiment of the present disclosure can further include a step of detecting a line width of the coating during the process of applying the coating. For example, the line width of the applied coating, (for example, sealant) can be obtained by a camera in combination with image analysis.

For example, in some embodiments, the operation method provided by at least one embodiment of the present disclosure can further include a step of performing an exposure operation to the surface plate to be processed that is adsorbed onto the bearing table via the mask plate; or a step of performing an exposure operation to the surface plate to be processed that is disposed with a mask layer and adsorbed onto the bearing table.

In order to facilitate comprehension of the operation method for the processing device provided by the embodiments of the present disclosure, in an example of an embodiment of the present disclosure, a case that the surface plate is a display panel is taken as an example, the operation method for the processing device can include the following steps.

Step 101: The electrostatic generator of the bearing table provides static electricity to the electrically conductive layer, such that the display panel (e.g., the array substrate in the display panel) can be fixed and adsorbed onto the bearing table through electrostatic adsorption provided by the conductive layer.

In Step 101, the electrostatic generator can control its output voltage to adjust the quantity of electric charges on the electrically conductive layer, so that the electrostatic adsorption force provided by the bearing table can be controlled. For example, increasing the output voltage of the electrostatic generator can increase the electrostatic adsorption force. For example, in order to allow the electrically conductive layer disposed on the bearing table to have good electrostatic effects, the current intensity after the voltage being applied to the electrically conductive layer by the electrostatic generator can be relatively small, and the maximum instant current is, for example, no larger than 1 mA.

Step 102: Applying a coating onto the array substrate.

In Step 102, for example, the coating can be a sealant. For example, in a case that the array substrate is divided into a display area and a non-display area surrounding the display area, the coating can be a sealant disposed in the non-display area.

Step 103: During a process of applying the coating, the line width of the coating is monitored by a detection unit (for example, an optical detection unit).

In Step 103, for example, the bearing table can be transparent and relevant contents of the bearing table (for example, the advantages of a transparent bearing table) can refer to the embodiment related to the bearing table of the present disclosure, no further descriptions will be given herein. Illustratively, the detection unit can be disposed on a side of the display panel far away from the coating head and the line width of the coating can be detected through the bearing table, so that the coating head and the detection unit can be disposed on opposite sides of the bearing table, and thus the operation method for the processing device can be simplified and the interference between the coating head and the detection unit can be prevented.

Step 104: For example, during the binding process of the display panel, the sealant of the display panel can be subjected to an exposure operation utilizing a mask plate disposed in the processing device. For example, the sealant can be hardened and fixed after being subjected to the exposure operation.

Due to the structures of the existing bearing tables are complex, the existing bearing tables usually have poor transparency and fabrication procedures using the existing bearing tables are limited. For example, a packaging and curing processes utilizing the existing bearing tables generally comprises the following steps: firstly, in one fabrication procedure, performing an exposure process (e.g., to cure sealant) to a plurality of locations of the display panel, so as to stabilize the structure of the display panel temporarily (e.g., after the array substrate and the opposed substrate being bind together, fixed-point exposure and curing process is performed); secondly, in a subsequent fabrication procedure, performing an overall exposure and curing process on the entire display panel. However, the packaging of the display panel resulted from the above-mentioned fabrication processes can be not sufficiently firm, product yield can be adversely affected and fabrication procedures can be complicated.

In the embodiments of the present disclosure, the bearing table can have a simple structure with high transparency, so that the exposure source used in exposure processes can be provide at a side of the display panel far away from the coating head and the exposure source can cure, for example, the sealant in the display panel via a mask plate or a mask layer. In this way, the binding process and the curing process of the display panel can be performed (for example, performed in parallel) in a same fabrication procedure, and thus product yield can be increased, manufacturing processes can be simplified and costs can be reduced as compared with a case in which the existing bearing tables is used.

It should be noted that the binding process of the display panel can adopt a conventional binding process and thus the implementation method can refer to conventional binding processes, and no further description will be given herein.

In the above-mentioned embodiments of the present disclosure, the mask used for the exposure of the surface plate can be implemented by the following two elements, that is, the mask plate and the mask layer, the concrete implementation methods of the mask plate and the mask layer can refer to relevant contents described in embodiments related to the processing device of the present disclosure, and no further description will be given herein. It should be noted that the mask suitable for exposure processes are not limited to the mask plate and the mask layer.

For example, the methods for the exposure of the surface plate using the processing device with the mask plate and using the processing device the mask layer are described with reference to the following two examples.

In one example of the present disclosure, a mask layer is formed on the surface plate (on a side of the surface plate facing toward the exposure source) to be processed that is adsorbed onto the bearing table, so that the surface plate can be processed by the exposure source transmitted through the mask layer in subsequent manufacturing processes for the surface plate.

It should be noted that the method utilizing the mask layer is suitable for processing (for example, curing and exposure processes in packaging) products (for example, surface plates to be processed) with various specifications. The embodiments related to the processing device described above in the present disclosure can be referred for detailed implementation methods and scopes, and thus no further description will be given herein.

For example, in another example of the present disclosure, a mask plate can be provided on a side of the insulation layer far away from the bearing substrate, so that the surface plate to be processed can be processed by the exposure source transmitted through the mask plate in subsequent manufacturing processes for the surface plate.

It should be noted that the method utilizing the mask plate is suitable for processing (for example, curing and exposure processes in packaging) products (for example, surface plates to be processed) with a single specification or of a few specifications. The embodiments related to the processing device described above in the present disclosure can be referred for detailed implementation methods and scopes, and thus no further description will be given herein.

Embodiments of the present disclosure provide a bearing table and a fabrication method thereof as well as a processing device and an operation method thereof, so as to achieve at least one of the following beneficial effects.

(1) The bearing table provided by the present disclosure can fix an object (for example, a surface plate to be processed) thereon through electrostatic adsorption, so that the structure of the bearing table can be simplified, costs of the bearing table can be reduced, the fixation method of the surface plate to be processed that is provided on the bearing table can be simplified, and the operation efficiency of the bearing table can be improved.

(2) The bearing table in the processing device provided by the present disclosure can be transparent, so that the processing device can process the surface plate to be processed at opposite surfaces (that is, the surface far away from the bearing table and the surface nearer to the bearing table) of the surface plate to be processed, and thus the manufacturing processes can be simplified.

The following statements should be noted:

(1) The accompanying drawings involve only the structure(s) in connection with the embodiment(s) of the present disclosure, and other structure(s) can be referred to common design(s).

(2) For the purpose of clarity only, in accompanying drawings for illustrating the embodiment(s) of the present disclosure, the thickness a layer or area can be enlarged or narrowed, that is, the drawings are not drawn in a real scale.

(3) In case of no conflict, features in one embodiment or in different embodiments can be combined.

What are described above is related to the illustrative embodiments of the disclosure only and not limitative to the scope of the disclosure; the scopes of the disclosure are defined by the accompanying claims.

The application claims priority to the Chinese patent application No. 201710144407.5, filed on Mar. 10, 2017, the entire disclosure of which is incorporated herein by reference as part of the present application.

What is claimed is:

1. A bearing table, comprising:
a bearing substrate;
an electrically conductive layer on the bearing substrate and configured to provide electrostatic adsorption; and
an insulation layer covering the electrically conductive layer on the bearing substrate.

2. The bearing table of claim 1, further comprising:
an electrostatic generator coupled to the electrically conductive layer and configured to provide static electricity to the electrically conductive layer.

3. The bearing table of claim 1, wherein
the bearing substrate and the insulation layer are transparent.

4. The bearing table of claim 3, wherein
the insulation layer comprises silicon nitride, silicon oxide or silicon oxynitride.

5. The bearing table of claim 1, wherein
the electrically conductive layer is a layer of wire pattern, the wire pattern comprises one or any combination of a polyline pattern, a camber line pattern, a homocentric squares pattern, and a grid pattern.

6. The bearing table of claim 5, wherein
the wire pattern comprises a transparent conductive material.

7. The bearing table of claim 2, wherein
the electrically conductive layer is a layer of wire pattern, the wire pattern comprises one or any combination of a polyline pattern, a camber line pattern, a homocentric squares pattern, and a grid pattern.

8. The bearing table of claim 3, wherein
the electrically conductive layer is a layer of wire pattern, the wire pattern comprises one or any combination of a polyline pattern, a camber line pattern, a homocentric squares pattern, and a grid pattern.

9. The bearing table of claim 4, wherein
the electrically conductive layer is a layer of wire pattern, the wire pattern comprises one or any combination of a polyline pattern, a camber line pattern, a homocentric squares pattern, and a grid pattern.

10. A processing device comprising the bearing table of claim 1

11. The processing device of claim 10, further comprising:
a coating head configured to apply a coating onto a surface plate to be processed that is placed on the bearing table.

12. The processing device of claim 11, further comprising:
a detection unit disposed on a side of the bearing substrate far away from the electrically conductive layer and configured to detect a line width of the coating.

13. The processing device of claim 10, further comprising: an exposure source, wherein
the exposure source is configured to perform an exposure operation via a mask plate adsorbed onto the bearing table.

14. The processing device of claim 10, further comprising: an exposure source, wherein
the exposure source is configured to perform an exposure operation via a mask layer disposed on a surface plate to be processed.

15. A fabrication method of a bearing table, comprising: providing a bearing substrate;
forming an electrically conductive layer on the bearing substrate, wherein the electrically conductive layer is operable to provide electrostatic adsorption; and
forming an insulation layer on the electrically conductive layer.

16. The fabrication method of claim 15, further comprising:
providing an electrostatic generator coupled to the electrically conductive layer.

17. An operation method for the processing device of claim 10, comprising:
enabling electrostatic adsorption via the electrically conductive layer

18. The operation method of claim 17, further comprising:
applying a coating onto a surface plate to be processed that is adsorbed onto the bearing table.

19. The operation method of claim 17, further comprising:
performing an exposure operation to a surface plate to be processed that is adsorbed onto the bearing table via a mask plate adsorbed onto the bearing table.

20. The operation method of claim 17, further comprising:
performing an exposure operation to a surface plate to be processed that is disposed with a mask layer and adsorbed onto the bearing table.
